(19) United States
(12) Patent Application Publication
(10) Pub. No.: US 2026/0316175 A1
(43) Pub. Date: Oct. 15, 2026

(54) WELDING WIRE SWITCHING APPARATUS AND METHODS

(71) Applicant: Novarc Technologies Inc., Burnaby (CA)

(72) Inventors: Maneet MAGHERA, Burnaby (CA); Trevor DUNNETT, North Vancouver (CA); Jess ORTON, Langley (CA); Ringo GONZALEZ, Fort Langley (CA); Jace REGEHR, Vancouver (CA)

(21) Appl. No.: 19/465,845

(22) Filed: Jan. 30, 2026

Related U.S. Application Data
(60) Provisional application No. 63/754,966, filed on Feb. 6, 2025.

(51) Int. Cl. B23K 9/12; B23K 9/10

(52) U.S. Cl. CPC B23K 9/124; B23K 9/1093

(57) ABSTRACT

An apparatus for switching welding wire delivered to a welding torch comprises a welding torch mounting bracket configured to hold a welding torch, and a welding wire switching mechanism comprising a fixed portion affixed to the welding torch mounting bracket, and a moveable portion pivotably coupled to the fixed portion. The moveable portion is configured to move between at least two operating positions and comprising at least two welding wire guides, wherein in each operating position one of the welding wire guides is aligned with a tip of the welding torch.

### CROSS-REFERENCE TO RELATED APPLICATION

The present application claims the benefit of and priority to United States Provisional Patent Application No. 63/754,966, filed Feb. 6, 2025, the entire content of which is incorporated herein by reference.

### TECHNICAL FIELD

The present disclosure relates to delivery of welding wire to a welding torch.

### BACKGROUND

Certain types of welding operations require different types of welding wire to be utilized in welding a workpiece. Typical approaches to address this need in robotic welding systems generally involve the use of different welding torches, or withdrawing one type of welding wire from a wire feeding cable leading to a welding torch and then inserting another type of welding wire through the wire feeding cable.

The inventors have determined a need for improved apparatus and methods for switching between different types of welding wire.

### SUMMARY

One aspect provides an apparatus comprising a welding torch mounting bracket configured to hold a welding torch, and a welding wire switching mechanism comprising a fixed portion affixed to the welding torch mounting bracket, and a moveable portion pivotably coupled to the fixed portion. The moveable portion is configured to move between at least two operating positions and comprising at least two welding wire guides, wherein in each operating position one of the welding wire guides is aligned with a tip of the welding torch.

In some embodiments, the fixed portion is electrically isolated from the welding torch mounting bracket, and the moveable portion is configured to be connected to a hot wire providing current thereto for pre-heating welding wire being delivered through the welding wire guides.

In some embodiments, the moveable portion comprises two arms extending in a radial direction from a pivot axis of the moveable portion, each arm having a welding wire guide mounted thereon.

In some embodiments, the welding wire guide of each arm is connected to a welding wire feeding cable connector received in a slot defined in that arm, such that a position of the welding wire guide is adjustable in a radial direction.

In some embodiments, the fixed portion comprises a ball detent therein, and the moveable portion comprises a ball detent catcher for each of the at least two operating positions.

In some embodiments, the moveable portion comprises a dowel pin extending from each side thereof, each dowel pin configured to abut an edge of the fixed portion when the moveable portion is in an operating position, such that the dowel pins constrain the motion of the moveable portion with respect to the fixed portion.

In some embodiments, the moveable portion is pivotally mounted to the fixed portion by a thrust bolt extending through the fixed portion and received in a pivot shaft of the moveable portion.

In some embodiments, the pivot shaft is received within a dry running bushing sleeve constructed from an insulating material disposed between the pivot shaft and a recess in the fixed portion, and the thrust bolt bears against a thrust washer constructed from an insulating material disposed between the thrust bolt and the fixed portion.

Further aspects of the present disclosure and details of example embodiments are set forth below.

### DRAWINGS

The following figures set forth embodiments in which like reference numerals denote like parts. Embodiments are illustrated by way of example and not by way of limitation in the accompanying figures.

FIG. 1 shows an example apparatus for switching welding wire according to one embodiment of the present disclosure.

FIGS. 2 and 3 show partially exploded views of the apparatus of FIG. 1 from different angles.

FIGS. 4 and 5 show rear views of the apparatus of FIG. 1 with the moveable portion of the wire switching mechanism in different positions for delivering different types of welding wire to a welding zone.

FIGS. 6 and 7 are photographs of a prototype apparatus according to another embodiment of the present disclosure.

### DETAILED DESCRIPTION

The following describes apparatus and methods for switching a type of welding wire delivered to a welding torch. The example embodiments discussed below provide a welding torch mounting bracket adapted for connection to a robotic arm, and having a wire switching mechanism coupled thereto. Some embodiments of the present disclosure can be used with many different types of existing welding torches and robotic arms. As used herein, the term “robotic arm” is used to refer to all types of mechanized manipulators. Examples of robotic welding systems to which apparatus according to the present disclosure could be used in conjunction with are disclosed, for example, in US Patent No. 10,661,396, US Patent Application Publication No. 2023/0339049 and PCT Publications No. WO2019153090 and No. WO202212627 to Novarc Technologies Inc., all of which are hereby incorporated by reference herein. The welding torch mounting apparatus and wire switching mechanisms disclosed herein can be mounted to all types of welding robots and mechanized arms.

For simplicity and clarity of illustration, reference numerals may be repeated among the figures to indicate corresponding or analogous elements. Numerous details are set forth to provide an understanding of the examples described herein. The examples may be practiced without these details. In other instances, well-known methods, procedures, and components are not described in detail to avoid obscuring the examples described. The description is not to be considered as limited to the scope of the examples described herein.

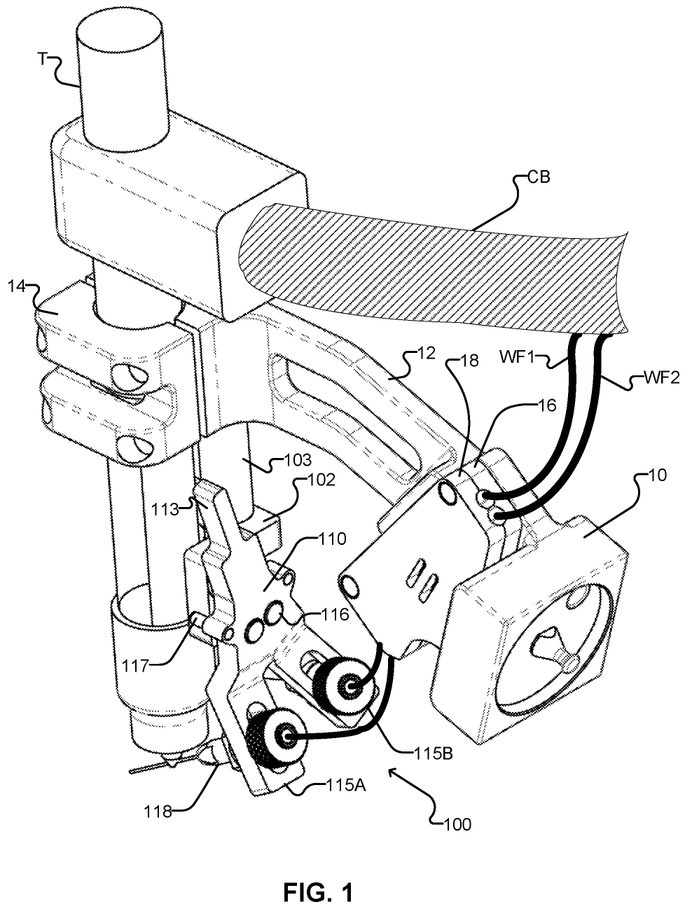

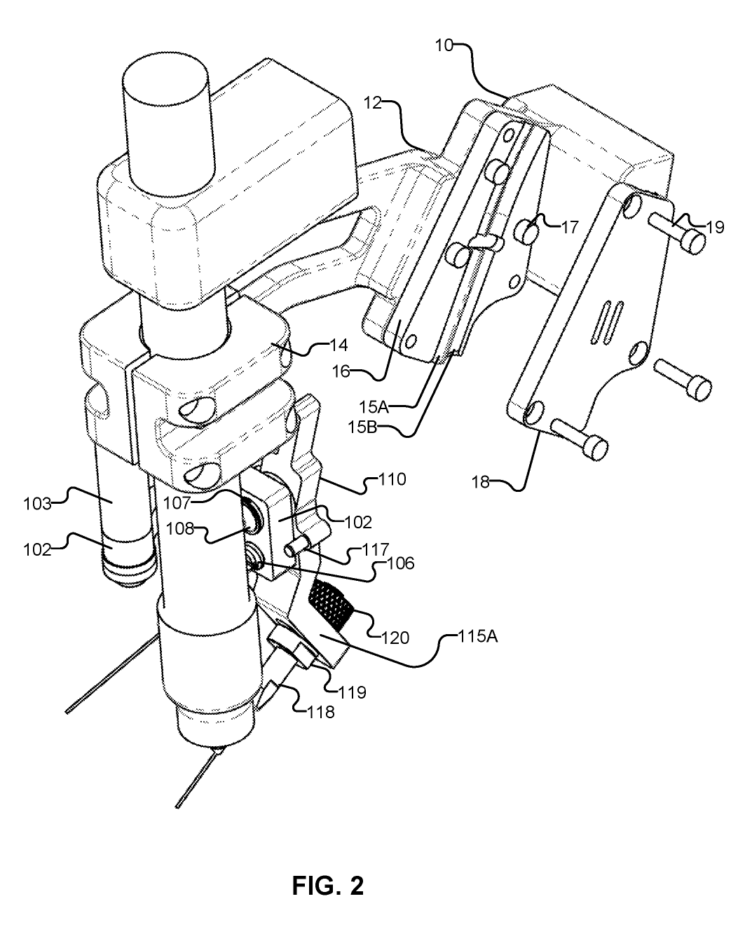

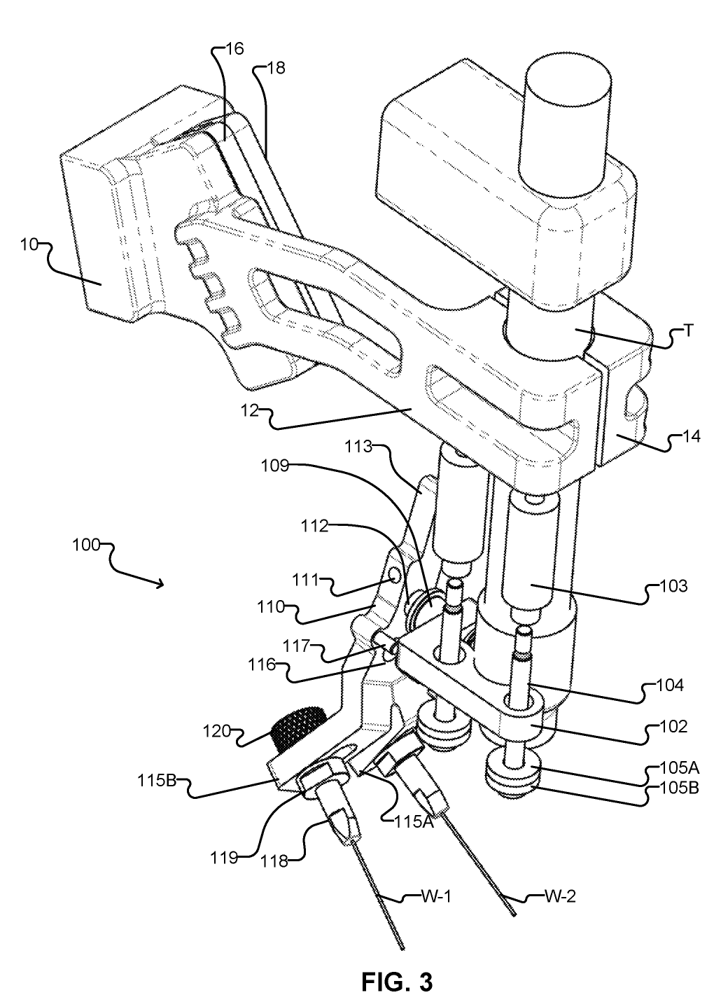

FIGS. 1-3 show an example apparatus for switching welding wire according to one embodiment of the present disclosure, in the form of a torch mounting bracket 10 configured to be connected to a robotic arm. The mounting bracket 10 has an extension portion 12 extending therefrom, with an end thereof configured to receive a torch clamp 14 (which may be connected to the extension portion by bolts, not shown) adapted to securely hold a welding torch T therein. In the illustrated example, bracket 10 is configured to engage a “quick release mechanism” of the type disclosed in US Patent Application Publication No. 2023/0339049, but it is to be understood that bracket 10 could be configured to engage other types of mechanisms, or to be bolted or otherwise secured to any type of robotic arm.

In the illustrated example, the torch T is operatively connected by a cable bundle CB to a base station comprising a welding power supply, robotic welding controller and/or other elements, and the cable bundle CB also includes first and second wire feeding cables WF1 and WF2, which are coupled to one or more wire feeders configured to deliver a first type of welding wire through cable WF1 and a second type of welding wire through cable WF2. The wire feeding cables WF1 and WF2 are received in channels formed by guide members 16/18 near the mounting bracket 10, and routed towards a wire switching mechanism 100. In the illustrated example, the guide members 16/18 each have grooves 15A and 15B on the inner faces thereof which form channels for receiving cables WF1 and WF2. Guide member 16 is secured to extension portion 12 by bolts 17, and guide member 18 is secured by bolts 19.

The wire switching mechanism 100 comprises a fixed portion 102 coupled to the extension portion 12 of the mounting bracket 10, and a moveable portion 110 pivotably coupled to the fixed portion 102. The moveable portion 110 of the wire switching mechanism 100 has two arms 115A and 115B, each of which supports a welding wire guide 118 oriented to direct a welding wire W-1/W-2 pushed out of a wire feeding cable WF1/WF2 towards a welding zone near the tip of the welding torch T. As described further the moveable portion 110 configured to move between two operating positions, wherein in each operating position one of the welding wire guides 118 is aligned with a tip of the welding torch.

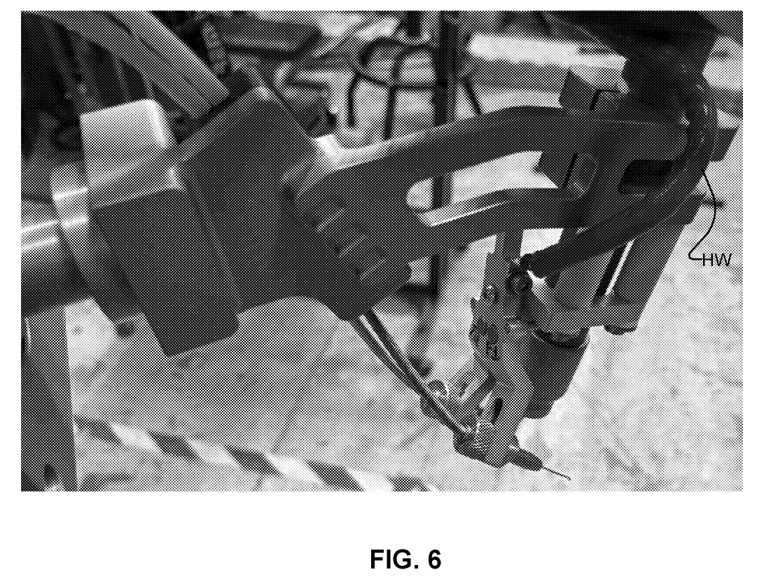

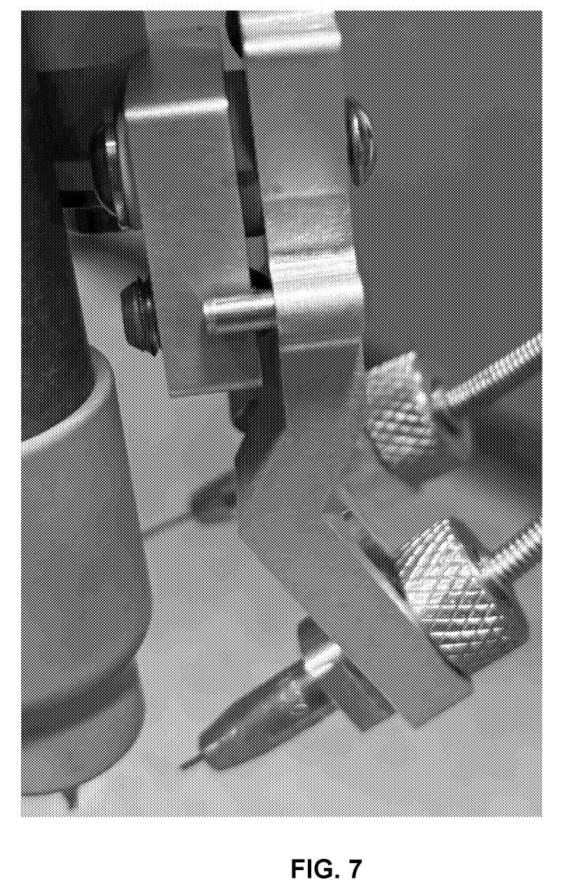

In the illustrated example, the moveable portion 110 comprises a connection point 111 for connecting a “hot wire” cable HW (not shown in FIG. 1, see FIG. 6) to provide current (e.g. 80 amps in some embodiments) to the moveable portion 110 to pre-heat the welding wire W-1/W-2. In such embodiments the switching mechanism 100 may be substantially electrically isolated from the mounting bracket 10.

The fixed portion 102 of the wire switching mechanism 100 is coupled to the extension portion 12 by bolts 104 which are sheathed in insulated spacer sleeves 103. The bolts 104 bear against metallic washers 105B, which in turn bear against insulating washers 105A, such that there is no electrical connection between the fixed portion 102 of the wire switching mechanism 100 and the extension portion 12.

The moveable portion 110 of the wire switching mechanism 100 comprises a pivot shaft 112 extending therefrom, which is received in a dry running sleeve bushing 109 inserted into a recess in the fixed portion of the wire switching mechanism 100. A thrust bolt 108 extends through the fixed portion 102 to be received in the pivot shaft 112, and bears against a thrust washer 107 constructed from an insulating material to further isolate current applied to the moveable portion 110 from the extension portion 12 of the mounting bracket 10.

In the illustrated example, a ball detent 106 is provided in the fixed portion 102 just “below” (i.e. closer to the tip of the welding torch) the thrust bolt 108, for holding the moveable portion 110 in one of a plurality of operating positions. The moveable portion 110 comprises a ball detent catcher 116 (which may comprise a magnet) associate with each of the arms 115A and 115B for holding the respective arm 115A/115B in an operating position wherein the welding wire guide 118 is aligned with the tip of the welding torch. In other embodiments, other mechanisms may be used to selectively hold the moveable portion 110 in place in one of the operating positions. The moveable portion 110 of the embodiment shown in FIG. 1 also comprises a dowel pin 117 extending from each side thereof. Each dowel pin 117 is configured to abut an edge of the fixed portion 102 when the moveable portion is in an operating position, such that the dowel pins constrain the motion of the moveable portion 100 with respect to the fixed portion. An operator can thus rapidly switch between welding wires W-1 and W-2 by simply pushing an upper portion 113 of the moveable portion 110 to one side or the other.

The welding wire guide 118 attached to each arm 115A/115B is connected to a wire feeding cable connector 119, which is received in a slot in the respective arm 115A/115B, and held in place by a connector nut 120. The position of the wire feeding cable connector 119 along the slot can be adjusted by loosening the connector nut 120, moving the wire feeding cable connector 119 up or down, and re-tightening the connector nut, such that an operator can quickly adjust the distance between the welding wire W-1/W-2 and the tip of the welding torch.

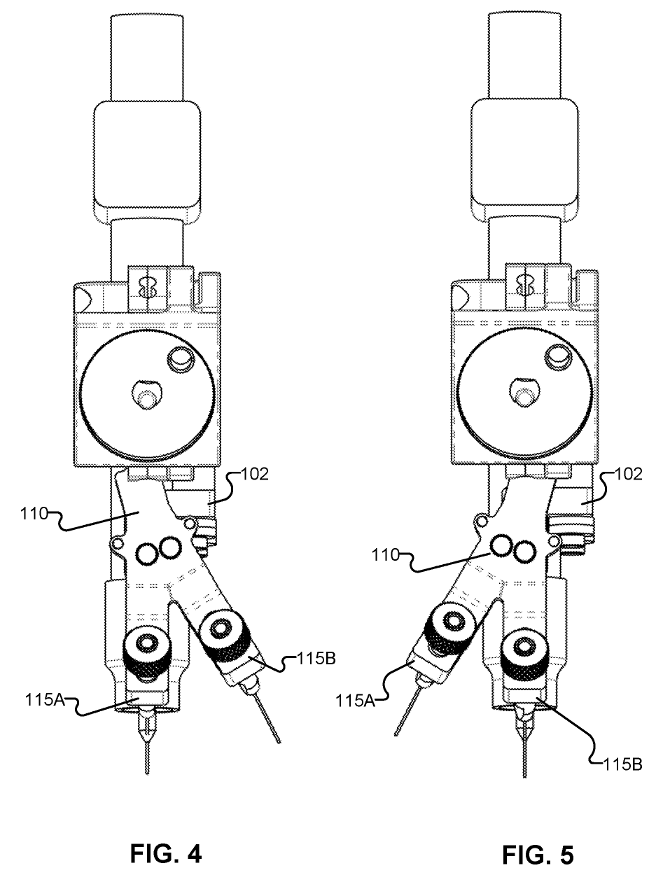

FIGS. 4 and 5 show rear views of the apparatus of FIG. 1 with the moveable portion of the wire switching mechanism in different positions for delivering different types of welding wire to a welding zone. In FIG. 4 the welding wire guide 118 of arm 115A is aligned with the tip of the welding torch, and in FIG. 5 the welding wire guide 118 of arm 115B is aligned with the tip of the welding torch.

FIGS. 6 and 7 are photographs of a prototype apparatus according to another embodiment of the present disclosure. In the prototype apparatus, the mounting bracket 10 and extension 12 are formed as a single piece constructed from a high quality aluminum (e.g. 6000 series), and the torch clamp 14 is also constructed from 6000 series aluminum. The guide members 16/18 are constructed from polytetrafluoroethylene (PTFE). The fixed portion 102 of the wire switching mechanism 100 is also constructed from a high quality aluminum. The bolts 104 connecting the fixed portion to the extension 12 are constructed from stainless steel, as are the washers 105B, whereas the insulating spacer sleeves 103 are constructed from Garolite™ G7 (e.g. a silicone resin with fiberglass fabric reinforcement), and the washers 105A are constructed from PTFE such that the fixed portion 102 is electrically isolated from the extension 12/bracket 10. The moveable portion 100 (including pivot shaft 112, upper portion 113 and arms 115A/115B) is formed as a single piece constructed from an even stronger high quality aluminum (e.g. 7000 series). The ball detent 106, thrust bolt 108, ball detent catchers 116, and dowel pins 117 are all constructed form stainless steel. The thrust washer 107 and the dry running sleeve bushing 109 are both constructed from Rulon™ J (e.g. a form of PTFE with proprietary filler). The welding wire guide 118 is constructed from copper, and the welding wire feeding cable connector 119 and connector nut 120 are constructed from brass.

### LIST OF REFERENCE NUMBERS

10 – torch mounting bracket (for connecting to robotic arm)

12 – torch mounting bracket extension

14 – torch clamp

15A/B – channels for feeding cables

16/18 – guide members for welding wire feeding cables

17-19 – bolts for guide members

100 – wire switching mechanism

102 – fixed portion

103 – insulated spacer sleeves

104 – bolts

105A – insulated washers

105B – metallic washers

106 – ball detent

107 – thrust washer

108 – thrust bolt

109 – dry running sleeve bushing

110 – moveable portion

111 – bolt hole for hot wire connection

112 –pivot shaft

113 – upper portion of moveable portion

115A/B – arms of moveable portion

116 – ball detent catchers/magnets

117 – dowel pins

118 – welding wire guide

119 – welding wire feeding cable connector

120 – connector nut

It will be appreciated that numerous specific details are set forth in order to provide a thorough understanding of the exemplary embodiments described herein. However, it will be understood by those of ordinary skill in the art that the embodiments described herein may be practiced without these specific details. In other instances, well-known methods, procedures and components have not been described in detail so as not to obscure the embodiments described herein. Furthermore, this description is not to be considered as limiting the scope of the embodiments described herein in any way, but rather as merely describing implementation of the various example embodiments described herein.

The description provides many example embodiments of the inventive subject matter. Although each embodiment represents a single combination of inventive elements, the inventive subject matter is considered to include all possible combinations of the disclosed elements. Thus if one embodiment comprises elements A, B, and C, and a second embodiment comprises elements B and D, then the inventive subject matter is also considered to include other remaining combinations of A, B, C, or D, even if not explicitly disclosed.

As will be apparent to those skilled in the art in light of the foregoing disclosure, many alterations and modifications are possible to the methods and systems described herein. While a number of exemplary aspects and embodiments have been discussed above, those of skill in the art will recognize certain modifications, permutations, additions and sub-combinations thereof. It is therefore intended that the following appended claims and claims hereafter introduced are interpreted to include all such modifications, permutations, additions and sub-combinations as may reasonably be inferred by one skilled in the art. The scope of the claims should not be limited by the embodiments set forth in the examples, but should be given the broadest interpretation consistent with the foregoing disclosure.

The present disclosure may be embodied in other specific forms without departing from its spirit or essential characteristics. The described embodiments are to be considered in all respects only as illustrative and not restrictive.

1. An apparatus comprising:
a. a welding torch mounting bracket configured to hold a welding torch; and
b. a welding wire switching mechanism comprising a fixed portion affixed to the welding torch mounting bracket, and a moveable portion pivotably coupled to the fixed portion, the moveable portion configured to move between at least two operating positions and comprising at least two welding wire guides, wherein in each operating position one of the welding wire guides is aligned with a tip of the welding torch.

2. The apparatus of claim 1, wherein the fixed portion is electrically isolated from the welding torch mounting bracket, and the moveable portion is configured to be connected to a hot wire providing current thereto for pre-heating welding wire being delivered through the welding wire guides.

3. The apparatus of claim 1, wherein the moveable portion comprises two arms extending in a radial direction from a pivot axis of the moveable portion, each arm having a welding wire guide mounted thereon.

4. The apparatus of claim 3, wherein the welding wire guide of each arm is connected to a welding wire feeding cable connector received in a slot defined in that arm, such that a position of the welding wire guide is adjustable in a radial direction.

5. The apparatus of claim 1, wherein the fixed portion comprises a ball detent therein, and the moveable portion comprises a ball detent catcher for each of the at least two operating positions.

6. The apparatus of claim 1, wherein the moveable portion comprises a dowel pin extending from each side thereof, each dowel pin configured to abut an edge of the fixed portion when the moveable portion is in an operating position, such that the dowel pins constrain the motion of the moveable portion with respect to the fixed portion.

7. The apparatus of claim 1, wherein the moveable portion is pivotally mounted to the fixed portion by a thrust bolt extending through the fixed portion and received in a pivot shaft of the moveable portion.

8. The apparatus of claim 7 wherein the pivot shaft is received within a dry running bushing sleeve constructed from an insulating material disposed between the pivot shaft and a recess in the fixed portion, and the thrust bolt bears against a thrust washer constructed from an insulating material disposed between the thrust bolt and the fixed portion.
